(19) United States
(12) Patent Application Publication
(10) Pub. No.: US 2026/0344164 A1
(43) Pub. Date: Oct. 29, 2026

(54) ARRAY SUBSTRATE, LIGHT-EMITTING SUBSTRATE AND DISPLAY APPARATUS

(71) Applicant: BOE Technology Group Co., Ltd., Beijing (CN)

(72) Inventor: Haixu LI, Beijing (CN)

(21) Appl. No.: 18/995,796

(22) PCT Filed: Sep. 28, 2023
(86) PCT No.: PCT/CN2023/122603

§ 371 Date: Jan. 16, 2025

(51) Int. Cl. H10H 29/856; H10H 29/49; H10H 29/853

(52) U.S. Cl. CPC H10H 29/856; H10H 29/49; H10H 29/853

(57) ABSTRACT

An array substrate, a light-emitting substrate, and a display apparatus are provided. The array substrate includes a base, a protrusion, a first reflective layer, a second reflective layer, and a conductive layer. The base includes a first surface and a second surface opposite to each other, and the first surface is provided with a groove. The protrusion is disposed within the groove and is spaced apart from a side surface of the groove. The first reflective layer at least covers a side surface of the protrusion. The second reflective layer is disposed on a side of the base away from the second surface and is provided with an opening. The conductive layer is disposed on a side of the second reflective layer facing away from the base, the conductive layer including a conductive pad.

### CROSS-REFERENCE TO RELATED APPLICATIONS

This application is the U.S. national phase of PCT Application No. PCT/CN2023/122603 filed on Sep. 28, 2023, the disclosure of which is incorporated herein by reference in its entirety.

### TECHNICAL FIELD

This application relates to the field of display technology, and in particular to an array substrate, a light-emitting substrate, and a display apparatus.

### BACKGROUND

With the development of Light-Emitting Diode (LED) technology, light-emitting substrates utilizing Mini-LEDs or even Micro-LEDs have been widely used. As a result, products utilizing such light-emitting substrates, such as Liquid Crystal Displays (LCDs), can not only have an image contrast reaching the level of that of Organic Light-Emitting Diode (OLED) display products, but also retain the technical advantages of liquid crystal display, thereby improving the image display effect and providing users with a better visual experience.

### SUMMARY

The present application provides an array substrate, a light-emitting substrate, and a display apparatus.

According to a first aspect of embodiments of the present application, there is provided an array substrate, including: a base including a first surface and a second surface opposite to each other, the first surface being provided with a groove; a protrusion disposed within the groove and spaced apart from a side surface of the groove, where areas of cross sections of the protrusion parallel to the second surface gradually increase in a direction from the first surface to the second surface; a first reflective layer at least covering a side surface of the protrusion; a second reflective layer disposed on a side of the base away from the second surface, the second reflective layer being provided with an opening, and an orthographic projection of the opening on the second surface being within an orthographic projection of the groove on the second surface; and a conductive layer on a side of the second reflective layer facing away from the base, the conductive layer including one or more conductive pads.

In an embodiment, the second reflective layer includes a first reflective portion, where an orthographic projection of the first reflective portion on the second surface does not overlap the orthographic projection of the groove on the second surface, and the first reflective portion is provided with a plurality of light homogenizing structures arranged in an array on a surface thereof facing the base.

In an embodiment, the light homogenizing structures include a plurality of concave structures arranged in an array, the array substrate further includes a plurality of supporting portions arranged in an array and disposed between the second reflective layer and the base, and the second reflective layer is in direct contact with the supporting portions.

In an embodiment, the array substrate further includes an encapsulation layer disposed between the base and the conductive layer, where the second reflective layer is disposed between the encapsulation layer and the base and the supporting portions are disposed on a side of the second reflective layer facing the base; or where the second reflective layer is disposed on a side of the encapsulation layer away from the base and the supporting portions are disposed between the second reflective layer and the encapsulation layer.

In an embodiment, the light homogenizing structures include a plurality of convex structures arranged in an array and facing the base, a plurality of concave portions arranged in an array are disposed on the first surface of the base, and the convex structures are disposed within the concave portions.

In an embodiment, an edge of the orthographic projection of the opening on the second surface is disposed inward of an edge of the orthographic projection of the groove on the second surface; and an orthographic projection of the second reflective layer on the second surface does not overlap an orthographic projection of the protrusion on the second surface.

In an embodiment, the second reflective layer includes a second reflective portion, an orthographic projection of the second reflective portion on the second surface falling within the orthographic projection of the groove on the second surface; the second reflective portion has a width of a first size; a longitudinal cross-section of the groove is a circular arc, which has a radius of a second size; and the first size is equal to the second size and is equal to a depth of the groove.

In an embodiment, a longitudinal cross-section of the protrusion is a circular arc, which has a radius of a third size, where the third size is equal to the depth of the groove.

In an embodiment, an orthographic projection of the second reflective layer on the second surface overlaps an orthographic projection of the first reflective layer on the second surface.

In an embodiment, the second reflective layer includes a first sub-reflective layer, a second sub-reflective layer on a side of the first sub-reflective layer away from the base, and a third sub-reflective layer on a side of the second sub-reflective layer away from the base; an orthographic projection of the first sub-reflective layer on the second surface does not overlap the orthographic projection of the groove on the second surface, and the first sub-reflective layer has a reflectivity greater than that of the second sub-reflective layer; and an orthographic projection of the second sub-reflective layer on the second surface overlaps the orthographic projection of the groove on the second surface, the third sub-reflective layer covers the second sub-reflective layer, and the third sub-reflective layer and the first reflective layer are made of a same material.

In an embodiment, a distance between a surface of the protrusion away from the second surface and the second surface is less than or equal to a distance between the first surface and the second surface.

In an embodiment, areas of cross sections of the groove parallel to the second surface gradually decrease in the direction from the first surface to the second surface.

In an embodiment, a bottom surface of the groove is planar in an area on both sides of the protrusion.

In an embodiment, an orthographic projection of a geometric center of the protrusion on the second surface coincides with an orthographic projection of a geometric center of the groove on the second surface.

In an embodiment, an outer contour of an orthographic projection of the protrusion on the second surface is a circle, and an outer contour of the orthographic projection of the groove on the second surface is a circle.

In an embodiment, a ratio of a radius of the outer contour of the orthographic projection of the protrusion on the second surface to a radius of the outer contour of the orthographic projection of the groove on the second surface is less than 0.5.

In an embodiment, the protrusion and the base are made of a same material.

In an embodiment, the protrusion and the base are of a monolithic structure.

In an embodiment, the array substrate further includes a color conversion structure disposed within the groove.

In an embodiment, there is an overlapping area between an orthographic projection of the second reflective layer on the second surface and the orthographic projection of the groove on the second surface; and the array substrate further includes a transparent organic layer disposed within the groove, an orthographic projection of the transparent organic layer on the second surface covering the overlapping area.

In an embodiment, the array substrate further includes an encapsulation layer between the base and the conductive layer; the second reflective layer includes a conductive material; and the encapsulation layer includes an inorganic film layer and an organic film layer, an orthographic projection of the organic film layer on the second surface covering an orthographic projection of the second reflective layer on the second surface.

In an embodiment, the base has a refractive index greater than that of air.

According to a second aspect of embodiments of the present application, there is provided a light-emitting substrate, including a plurality of light-emitting elements and the array substrate as described above, where each of the light-emitting elements includes a plurality of pins, each of which is bound and connected to one of the conductive pads.

In an embodiment, the light-emitting substrate further includes a third reflective layer, where the third reflective layer covers the light-emitting elements, and the third reflective layer is provided with a light-exit hole on a side thereof facing the array substrate.

According to a third aspect of embodiments of the present application, there is provided a display apparatus, including a display panel and the light-emitting substrate as described above, where the display panel is disposed on a side of the base away from the light-emitting elements.

With an array substrate, a light-emitting substrate, and a display apparatus according to embodiments of the present application, a base is provided with a groove in a first surface thereof, and cross sections of a protrusion within the groove of the base gradually increase in a direction from the first surface of the base to a second surface of the base. Light which is incident from a side of the first surface of the base to a first reflective layer covering a side of the protrusion is reflected by the first reflective layer, and is incident to a second reflective layer to be reflected by the second reflective layer again. One portion of the light reflected by the second reflective layer is emitted directly through a surface of the base facing away from the second reflective layer, and the other portion of the light is emitted through the surface of the base facing away from the second reflective layer after multiple reflections within the base, such that the uniformity of the emitted light can be improved. In this way, the array substrate can be provided with no light homogenizing film layers, or with a reduced number of light homogenizing film layers, which is beneficial to reducing the thickness of the array substrate.

### BRIEF DESCRIPTION OF DRAWINGS

FIG. 1A is a partial cross-sectional view of an array substrate according to an exemplary embodiment of the present application.

FIG. 1B is a partial cross-sectional view of an array substrate according to another exemplary embodiment of the present application.

FIG. 2 is a partial cross-sectional view of an array substrate according to yet another exemplary embodiment of the present application.

FIG. 3 is a partial cross-sectional view of an array substrate according to yet another exemplary embodiment of the present application.

FIG. 4 is a partial cross-sectional view of an array substrate according to still another exemplary embodiment of the present application.

FIG. 5 is a top view of an array substrate according to an exemplary embodiment of the present application.

FIG. 6 is a partial enlarged view of the array substrate shown in FIG. 2.

FIG. 7 is a partial enlarged view of the array substrate shown in FIG. 3.

FIG. 8 is a flowchart of a method of preparing an array substrate according to an exemplary embodiment of the present application.

FIG. 9A is a partial cross-sectional view of a first intermediate structure of an array substrate according to an exemplary embodiment of the present application.

FIG. 9B is a partial top view of a first intermediate structure of an array substrate according to an exemplary embodiment of the present application.

FIG. 10 is a partial cross-sectional view of a second intermediate structure of an array substrate according to an exemplary embodiment of the present application.

FIG. 11 is a partial cross-sectional view of a third intermediate structure of an array substrate according to an exemplary embodiment of the present application.

FIG. 12 is a partial cross-sectional view of a fourth intermediate structure of an array substrate according to an exemplary embodiment of the present application.

FIG. 13 is a partial cross-sectional view of a fifth intermediate structure of an array substrate according to an exemplary embodiment of the present application.

FIG. 14 is a partial cross-sectional view of a sixth intermediate structure of an array substrate according to an exemplary embodiment of the present application.

FIG. 15 is a partial cross-sectional view of a first intermediate structure of an array substrate according to another exemplary embodiment of the present application.

FIG. 16 is a partial enlarged view of the first intermediate structure shown in FIG. 15.

FIG. 17 is a partial cross-sectional view of a second intermediate structure of an array substrate according to another exemplary embodiment of the present application.

FIG. 18 is a partial cross-sectional view of a third intermediate structure of an array substrate according to another exemplary embodiment of the present application.

FIG. 19 is a partial cross-sectional view of a seventh intermediate structure of an array substrate according to an exemplary embodiment of the present application.

FIG. 20 is a partial cross-sectional view of a first intermediate structure of an array substrate according to yet another exemplary embodiment of the present application.

FIG. 21 is a partial enlarged view of the first intermediate structure shown in FIG. 20.

FIG. 22 is a partial cross-sectional view of a second intermediate structure of an array substrate according to yet another exemplary embodiment of the present application.

FIG. 23 is a partial cross-sectional view of a third intermediate structure of an array substrate according to yet another exemplary embodiment of the present application.

FIG. 24 is a partial cross-sectional view of a first intermediate structure of an array substrate according to still another exemplary embodiment of the present application.

FIG. 25 is a partial cross-sectional view of a second intermediate structure of an array substrate according to still another exemplary embodiment of the present application.

FIG. 26 is a partial cross-sectional view of an eighth intermediate structure of an array substrate according to an exemplary embodiment of the present application.

FIG. 27 is a partial cross-sectional view of a ninth intermediate structure of an array substrate according to an exemplary embodiment of the present application.

FIG. 28 is a partial cross-sectional view of a tenth intermediate structure of an array substrate according to an exemplary embodiment of the present application.

FIG. 29 is a partial cross-sectional view of an eleventh intermediate structure of an array substrate according to an exemplary embodiment of the present application.

FIG. 30 is a partial cross-sectional view of a twelfth intermediate structure of an array substrate according to an exemplary embodiment of the present application.

FIG. 31 is a partial cross-sectional view of a thirteenth intermediate structure of an array substrate according to an exemplary embodiment of the present application.

FIG. 32 is a partial cross-sectional view of a light-emitting substrate according to an exemplary embodiment of the present application.

FIG. 33 is a top view of a light-emitting substrate according to an exemplary embodiment of the present application.

### DETAILED DESCRIPTION

Reference will now be made in detail to exemplary embodiments, examples of which are illustrated in the accompanying drawings. When the following description refers to the drawings, the same numbers in different drawings indicate the same or similar elements, unless otherwise indicated. The embodiments described in the following exemplary embodiments are not intended to be representative of all embodiments consistent with the present application. Rather, they are merely examples of apparatuses and methods consistent with some aspects of the present application as detailed in the appended claims.

Terminology used herein is for the purpose of describing particular embodiments only and is not intended to be limiting of the present application. As used in the present application and the appended claims, the singular forms of “a,” “an,” “said,” and “the” are intended to include the plural forms as well, unless the context clearly dictates otherwise. It should also be understood that the term “and/or” as used herein refers to and encompasses any or all possible combinations of one or more of the associated listed items.

It should be understood that, although terms first, second, third, and the like, may be used herein to describe various types of information, such information should not be limited by these terms. These terms are used only to distinguish the same type of information from one another. For example, first information may also be referred to as second information, and similarly, second information may also be referred to as first information, without departing from the scope of the present application. Depending on the context, the word “if” as used herein may be interpreted as “upon” or “when” or “in response to determining”.

Embodiments of the present application provide an array substrate, a light-emitting substrate, and a display apparatus. The array substrate, the light-emitting substrate, and the display apparatus according to the embodiments of the present application will be described in detail below with reference to the accompanying drawings. Features in the embodiments described below may complement each other or be combined with each other without conflict.

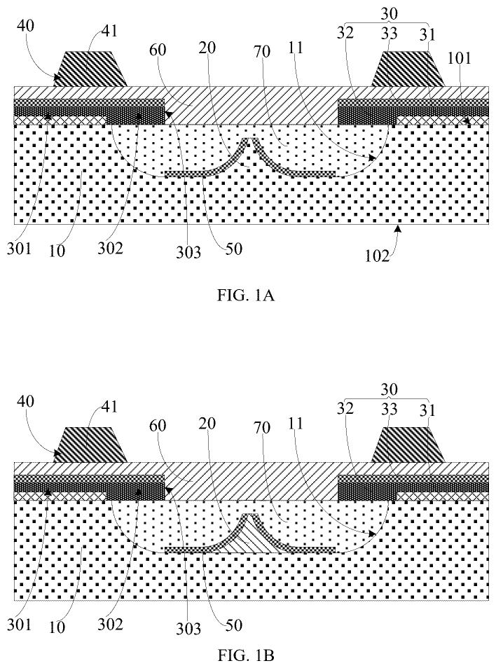

Embodiments of the present application provide an array substrate. As shown in FIGS. 1A to 5, the array substrate includes a base 10, a protrusion 20, a first reflective layer 50, a second reflective layer 30, and a conductive layer 40.

The base 10 includes a first surface 101 and a second surface 102 which are opposite to each other, and the first surface 101 is provided with a groove 11. The protrusion 20 is disposed within the groove 11 and is spaced apart from a side surface of the groove 11. In a direction from the first surface 101 to the second surface 102, areas of cross sections of the protrusion 20 parallel to the second surface 102 gradually increase. The first reflective layer 50 at least covers a side surface of the protrusion 20. The second reflective layer 30 is disposed on a side of the base 10 away from the second surface 102, and the second reflective layer 30 is provided with an opening 303, where an orthographic projection of the opening 303 on the second surface 102 of the base 10 is located within an orthographic projection of the groove 11 on the second surface 102 of the base 10. The conductive layer 40 is disposed on a side of the second reflective layer 30 facing away from the base 10, and the conductive layer 40 includes one or more conductive pads 41.

With an array substrate according to embodiments of the present application, a base is provided with a groove in a first surface thereof, and cross sections of a protrusion within the groove of the base gradually increase in a direction from the first surface of the base to a second surface of the base. Light which is incident from a side of the first surface of the base to a first reflective layer covering a side of the protrusion is reflected by the first reflective layer, and is incident to a second reflective layer to be reflected by the second reflective layer again. One portion of the light reflected by the second reflective layer is emitted directly through a surface of the base facing away from the second reflective layer, and the other portion of the light is emitted through the surface of the base facing away from the second reflective layer after multiple reflections within the base, such that the uniformity of the emitted light can be improved. In this way, the array substrate can be provided with no light homogenizing film layers, or with a reduced number of light homogenizing film layers, which is beneficial to reducing the thickness of the array substrate.

In the embodiments of the present application, the side surface of the groove 11 refers to a continuous portion of an inner surface of the groove 11, which is opposite to the protrusion 20. A bottom surface of the groove 11 refers to a continuous portion of the inner surface of the groove 11, which is not opposite to the protrusion 20 and is continuous with a bottom surface of the protrusion 20. A distance from any point on the bottom surface of the groove 11 to the second surface 102 of the base 10 is not greater than a distance from any point on the side surface of the groove 11 to the second surface 102 of the base 10.

In an embodiment, the base 10 has a refractive index greater than that of air. In this way, when the light reflected by the second reflective layer 30 is incident to the second surface 102 of the base 10, a portion of the light can be totally reflected and incident to the second reflective layer 30 again, which can further improve the uniformity of the emitted light. In some embodiments, the base 10 may be made of any one of glass, quartz, Polymethyl Methacrylate (PMMA), and the like.

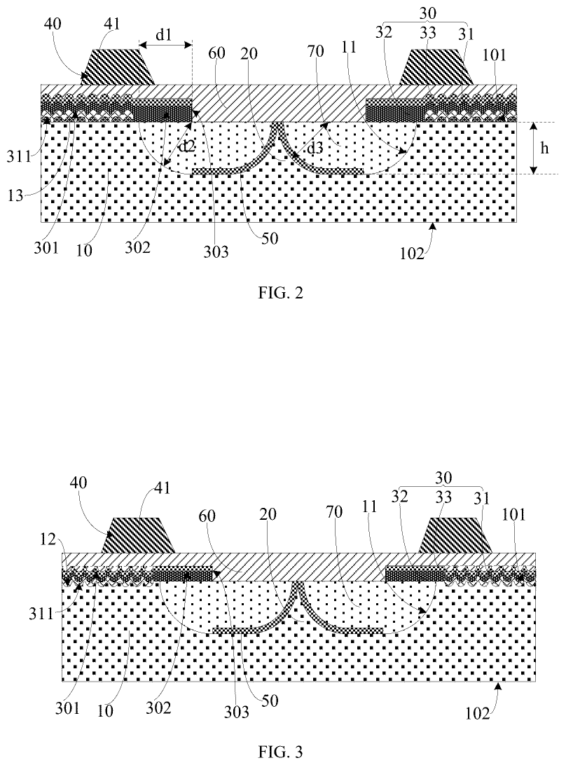

In an embodiment, a distance between a surface of the protrusion 20 away from the second surface 102 and the second surface 102 is less than or equal to a distance from the first surface 101 to the second surface 102. In the embodiments shown in FIG. 1A and FIG. 1B, the distance between the surface of the protrusion 20 away from the second surface 102 and the second surface 102 is less than the distance from the first surface 101 to the second surface 102. In the embodiments shown in FIG. 2 to FIG. 4, the distance between the surface of the protrusion 20 away from the second surface 102 and the second surface 102 is equal to the distance from the first surface 101 to the second surface 102.

In an embodiment, the protrusion 20 is made of a material the same as or similar to that of the base 10, so as to improve the optical consistency of structures at corresponding positions.

Further, as shown in FIG. 1A, the protrusion 20 and the base 10 are of a monolithic structure. In another embodiment, as shown in FIG. 1B, the protrusion 20 is not integrally formed with the base 10.

In an embodiment, a longitudinal cross-section of the protrusion 20 is circular-arc-like, straight-line-like, or polyline-like in shape. “Circular-arc-like” refers to a generally circular arc shape, but is not limited to a standard circular arc. In other words, “circular arc” herein includes not only a shape of a basic circular arc, but also a shape similar to a circular arc. For example, there are some points in the longitudinal cross-section of the protrusion 20 that are not on the same circle as other points. “Straight-line-like” refers to a straight line as a whole, but is not limited to a standard straight line. In other words, “straight line” herein includes not only a shape of a basic straight line but also a shape similar to a straight line. For example, there are some points in the longitudinal cross-section of the protrusion 20 that are not in a straight line with other points. “Polyline-like” refers to a polyline as a whole, but is not limited to a standard polyline. In other words, “polyline” herein includes not only a shape of a basic polyline, but also a shape similar to a polyline. For example, a portion of the longitudinal cross-section of the protrusion 20 is curved. “Longitudinal” refers to a direction perpendicular to the second surface 102 of the base.

In an embodiment, as shown in FIG. 1A to FIG. 5, the base 10 is provided with a plurality of grooves 11 arranged at intervals, the second reflective layer 30 is provided with a plurality of openings 303, and the openings 303 are in one-to-one correspondence with the grooves 11. An orthographic projection of each of the openings 303 on the second surface 102 of the base 10 is located within an orthographic projection of a respective groove 11 on the second surface 102 of the base 10. It should be noted that FIG. 5 is a schematic diagram, and in practice, the number of the grooves 11 of the array substrate is much greater than the number of the grooves 11 in FIG. 5.

In an embodiment, in the direction from the first surface 101 to the second surface 102, areas of cross sections of the groove 11 parallel to the second surface 102 gradually decrease.

In an embodiment, as shown in FIG. 1A to FIG. 4, the bottom surface of the groove 11 is planar in an area surrounding the protrusion 20.

In an embodiment, a line connecting a geometric center of the protrusion 20 and a geometric center of the groove 11 is perpendicular to the second surface 102 of the base 10.

Further, a center of an orthographic projection of the protrusion 20 on the second surface 102 of the base 10 coincides with a center of the orthographic projection of the groove 11 on the second surface 102 of the base 10.

Further, as shown in FIG. 5, an outer contour of the orthographic projection of the protrusion 20 on the second surface 102 of the base 10 is a circle, and an outer contour of the orthographic projection of the groove 11 on the second surface 102 of the base 10 is a circle. A center of the outer contour of the orthographic projection of the protrusion 20 on the second surface 102 of the base 10 coincides with a center of the outer contour of the orthographic projection of the groove 11 on the second surface 102 of the base 10.

Further, the protrusion 20 includes a vertex, and an orthographic projection of the vertex of the protrusion 20 on the second surface 102 of the base 10 coincides with the center of the orthographic projection of the groove 11 on the second surface 102 of the base 10.

In an embodiment, a ratio of a radius of the outer contour of the orthographic projection of the protrusion 20 on the second surface 102 of the base 10 to a radius of the outer contour of the orthographic projection of the groove 11 on the second surface 102 of the base 10 is less than 0.5.

In an embodiment, the conductive layer 40 further includes a plurality of signal lines for providing signals to an inorganic light-emitting diode and/or a driver chip. The plurality of signal lines may include a common voltage line, a driving voltage line, a source power line, a source address line, a clock signal line, a data line, and the like. In some embodiments, the conductive layer 40 may have a thickness ranging from 2 μm to 7 μm.

In an embodiment, as shown in FIG. 1A to FIG. 4, the array substrate further includes a color conversion structure 70 within the groove 11. The color conversion structure 70 may cover the first reflective layer 50. When a light-emitting element of a light-emitting substrate in which the array substrate is located emits non-white light, the color conversion structure 70 converts the non-white light into white light under the excitation of the non-white light, so as to improve the utilization of light energy. The color conversion structure 70 is disposed within the groove 11, such that the color conversion structure 70 does not increase the thickness of the array substrate, which is helpful to realize lightening and thinning of the array substrate. In some embodiments, a material of the color conversion structure 70 may include at least one of a quantum dot material or a fluorescent material.

In an embodiment, the material of the color conversion structure 70 of the array substrate includes quantum dot materials of different colors. For example, when the light-emitting element emits blue light, the material of the color conversion structure 70 of the array substrate may include a red quantum dot material, a green quantum dot material, and a transparent material, and the same color conversion structure 70 includes a quantum dot material of one color. The blue light is converted into red light when it passes through the red quantum dot material. The blue light is converted into green light when it passes through the green quantum dot material. The blue light may directly pass through the transparent material. The blue light, the red light, and the green light are mixed and superimposed in a certain ratio to appear as white light.

In other embodiments, when the light-emitting element emits white light, there is no need to fill the groove 11 with the color conversion structure 70, and in this case, the groove 11 may be filled with a transparent organic resin. A light transmittance of the transparent organic resin may be greater than or equal to 95%, and a refractive index of the transparent organic resin is less than that of the base 10.

In an embodiment, a distance between a surface of the color conversion structure 70 away from the second surface 102 and the second surface 102 is less than or equal to the distance from the first surface 101 to the second surface 102. In the embodiments shown in FIG. 1A to FIG. 4, the distance between the surface of the color conversion structure 70 away from the second surface 102 and the second surface 102 is equal to the distance from the first surface 101 to the second surface 102. In other embodiments, the distance between the surface of the color conversion structure 70 away from the second surface 102 and the second surface 102 may be less than the distance from the first surface 101 to the second surface 102.

In an embodiment, as shown in FIG. 1A to FIG. 4, the array substrate further includes an encapsulation layer 60 disposed between the base 10 and the conductive layer 40. The encapsulation layer 60 covers the color conversion structure 70. In this way, the encapsulation layer 60 can protect the color conversion structure 70, thereby reducing the risk of failure of the color conversion structure 70 due to water and oxygen erosion.

In an embodiment, the encapsulation layer 60 includes an organic film layer and an inorganic film layer, and a film layer farthest from the base 10 is the inorganic film layer. The encapsulation layer 60 may include a plurality of inorganic film layers, and a material of the inorganic film layers may include, for example, at least one of silicon carbonitride or silicon oxide.

In an embodiment, the encapsulation layer 60, as a whole, is a continuous film layer covering a plurality of color conversion structures 70 and gaps between adjacent color conversion structures 70. In some embodiments, an area of an orthographic projection of the encapsulation layer 60 on the second surface 102 of the base is the same as an area of the second surface 102. Alternatively, as shown in FIG. 5, the array substrate includes a central area 110 and an edge area 120 on at least one side of the central area 110, all of the grooves 11 are located in the central area 110 of the base 10, and the encapsulation layer 60 covers the central area 110 of the base 10, but does not cover the edge area 120 of the base 10. In the embodiment shown in FIG. 5, the edge area 120 surrounds the central area 110.

In an embodiment, the second reflective layer 30 includes a conductive material. An orthographic projection of the organic film layer of the encapsulation layer 60 on the second surface 102 of the base 10 covers an orthographic projection of the second reflective layer 30 on the second surface 102 of the base 10. The organic film layer has a larger thickness. The orthographic projection of the organic film layer on the second surface 102 of the base 10 covers the orthographic projection of the second reflective layer 30 on the second surface 102 of the base 10, which can reduce the signal interference of the second reflective layer 30 on the conductive layer 40. In some embodiments, the thickness of the organic film layer ranges from 2 μm to 10 μm, a thickness of the inorganic film layer on a side of the organic film layer away from the base ranges from 1000 angstroms to 5000 angstroms, and a total thickness of the inorganic film layers in the encapsulation layer 60 ranges from 0.5 μm to 1 μm. In some embodiments, the thickness of the organic film layer may be, for example, 2 μm, 4 μm, 6 μm, 8 μm, 10 μm, etc. The thickness of the inorganic film layer on the side of the organic film layer away from the base may be, for example, 1000 angstroms, 2000 angstroms, 3000 angstroms, 4000 angstroms, 5000 angstroms, etc. The total thickness of the inorganic film layers in the encapsulation layer 60 may be, for example, 0.5 μm, 0.6 μm, 0.7 μm, 0.8 μm, 0.9 μm, 1.0 μm, etc.

In an embodiment, the first reflective layer 50 has a reflectivity greater than or equal to 85%. In some embodiments, a material of the first reflective layer 50 may include a metal, for example, at least one of aluminum, silver, copper, or platinum. Alternatively, the material of the first reflective layer 50 may include white ink and/or silicon-based white glue.

In an embodiment, as shown in FIG. 1A to FIG. 5, an edge of the orthographic projection of the opening 303 of the second reflective layer 30 on the second surface 102 of the base 10 is located inward of an edge of the orthographic projection of a corresponding groove 11 on the second surface 102 of the base 10. The orthographic projection of the second reflective layer 30 on the second surface 102 of the base 10 does not overlap the orthographic projection of the protrusion 20 on the second surface 102 of the base 10. In this way, a portion of the light reflected by the first reflective layer 50 is incident to a portion of the second reflective layer 30 opposite to the groove 11, and is finally emitted from a surface of the base 10 away from the second reflective layer 30, which helps to improve the luminous efficiency compared to the scheme in which the second reflective layer 30 does not include a portion opposite to the groove 11. In addition, the second reflective layer 30 can also serve as a mask when the groove 11 is formed, such that cost and time can be saved in the process step of forming the groove 11, and the preparation cost of the array substrate can be reduced. Since the orthographic projection of the second reflective layer 30 on the second surface 102 of the base 10 does not overlap the orthographic projection of the protrusion 20 on the second surface 102 of the base 10, the second reflective layer 30 does not impede the propagation of the light emitted by the light-emitting element towards the first reflective layer 50.

In an embodiment, as shown in FIG. 1A to FIG. 4, the second reflective layer 30 includes a first reflective portion 301 and a second reflective portion 302. An orthographic projection of the first reflective portion 301 on the second surface 102 of the base 10 does not overlap the orthographic projection of the groove 11 on the second surface 102 of the base 10. An orthographic projection of the second reflective portion 302 on the second surface 102 of the base 10 falls within the orthographic projection of the groove 11 on the second surface 102 of the base 10.

In an embodiment, as shown in FIG. 1A to FIG. 4, the first reflective portion 301 includes a first sub-reflective layer 31, a second sub-reflective layer 32 on a side of the first sub-reflective layer 31 away from the base 10, and a third sub-reflective layer 33 on a side of the second sub-reflective layer 32 away from the base 10. The second reflective portion 302 includes a second sub-reflective layer 32, and a third sub-reflective layer 33 on a side of the second sub-reflective layer 32 away from the base. The second sub-reflective layer 32 of the first reflective portion 301 is continuous with the second sub-reflective layer 32 of the second reflective portion 302, and the third sub-reflective layer 33 of the first reflective portion 301 is continuous with the third sub-reflective layer 33 of the second reflective portion 302.

In an embodiment, an orthographic projection of the first sub-reflective layer 31 on the second surface 102 of the base 10 does not overlap the orthographic projection of the groove 11 on the second surface 102 of the base 10. A reflectivity of the first sub-reflective layer 31 is greater than that of the second sub-reflective layer 32. Due to the higher reflectivity of the first sub-reflective layer 31, the light reflected by the first reflective layer 50 can be reflected more by the first sub-reflective layer 31 after being incident to the first sub-reflective layer 31, thereby increasing the light emission rate and reducing the light loss.

In some embodiments, the reflectivity of the first sub-reflective layer 31 is greater than or equal to 85%. For example, a material of the first sub-reflective layer 31 may include a metal, for example, at least one of aluminum, silver, copper, or platinum. By way of example, the material of the first sub-reflective layer 31 may include white ink and/or silicon-based white glue.

In an embodiment, an orthographic projection of the second sub-reflective layer 32 on the second surface 102 of the base 10 overlaps the orthographic projection of the groove 11 on the second surface 102 of the base 10. In this way, the second sub-reflective layer 32 can serve as a mask when the groove is formed. In some embodiments, a material of the second sub-reflective layer 32 may include a metal, such as molybdenum, such that the second sub-reflective layer 32 has better corrosion resistance, and a portion of the second sub-reflective layer 32 beyond the first sub-reflective layer 31 is less prone to collapse during etching of the base with an etching solution. Moreover, the second sub-reflective layer 32 covers an edge of the first sub-reflective layer 31, and the second sub-reflective layer 32 can protect the first sub-reflective layer 31 during etching of the base with the etching solution.

In an embodiment, the third sub-reflective layer 33 covers the second sub-reflective layer 32, and a material of the third sub-reflective layer 33 is the same as that of the first reflective layer 50. An orthographic projection of the third sub-reflective layer 33 on the second surface 102 of the base 10 may coincide with the orthographic projection of the second sub-reflective layer 32 on the second surface 102 of the base 10. Since the third sub-reflective layer 33 covers the second sub-reflective layer 32, a portion of the second reflective layer 30 opposite to the groove 11 may have an increased thickness and strength, which is helpful to prevent collapse of the portion of the second reflective layer 30 opposite to the groove 11 before the color conversion structure or the transparent organic resin is formed within the groove 11. Since the material of the third sub-reflective layer 33 is the same as that of the first reflective layer 50, the third sub-reflective layer 33 and the first reflective layer 50 can be formed at the same time, which is helpful to simplify the preparation process.

In an embodiment, the orthographic projection of the second reflective layer 30 on the second surface 102 of the base 10 overlaps the orthographic projection of the first reflective layer 50 on the second surface 102 of the base 10. In the embodiments shown in FIG. 1A to FIG. 4, an edge of the orthographic projection of the second reflective portion 302 on the second surface 102 of the base 10 overlaps an outer edge of the orthographic projection of the first reflective layer 50 on the second surface 102 of the base 10. In this way, the first reflective layer 50 does not cover the side surface of the groove 11, such that the amount of light reflected by the first reflective layer 50 and emitted through the opening of the groove 11 can be reduced, and the amount of light emitted from the second surface 102 of the base 10 can be increased. In other embodiments, the orthographic projection of the second reflective portion 302 on the second surface 102 of the base 10 partially overlaps the orthographic projection of the first reflective layer 50 on the second surface 102 of the base 10, that is, the first reflective layer 50 covers a portion of the side surface of the groove 11.

In an embodiment, as shown in FIG. 2 and FIG. 3, the first reflective portion 301 is provided with a plurality of light homogenizing structures 311 arranged at intervals on a surface facing the base 10. The light homogenizing structures 311 can scatter the light incident to the second reflective layer 30 in various directions. Specifically, the light reflected by the first reflective layer 50 is scattered by the light homogenizing structures 311 after being incident to the second reflective layer 30 to change a propagation direction of the light, and is reflected by the second reflective layer 30 to be emitted from the surface of the base away from the second reflective layer 30, which can improve the brightness uniformity of the light-emitting substrate.

In an embodiment, the light homogenizing structures 311 are uniformly dispersed throughout the surface of the first reflective portion facing the base 10. A distance between an edge of the first sub-reflective layer 31 close to the groove 11 and the groove 11 is less than or equal to 5 μm. In this way, it can be avoided that the light reflected by the first reflective layer, when incident to an area between the edge of the first sub-reflective layer 31 close to the groove 11 and the groove 11, cannot contact the light homogenizing structures, resulting in insufficient scattering of the light, in the case that the distance between the edge of the first sub-reflective layer 31 close to the groove 11 and the groove 11 is too large.

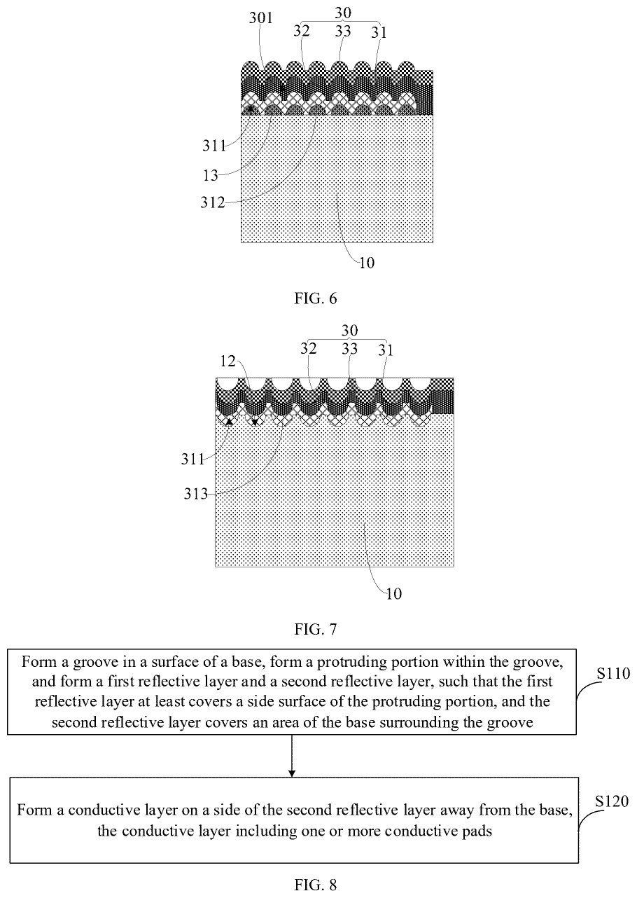

In an embodiment, as shown in FIG. 2 and FIG. 6, the light homogenizing structures 311 include a plurality of concave structures 312 arranged in an array. The array substrate further includes a plurality of supporting portions 13 arranged in an array between the second reflective layer 30 and the base 10. The second reflective layer 30 is in direct contact with the supporting portions 13. The supporting portions 13 are provided to facilitate the formation of the concave structures 312.

In an embodiment, a material of the supporting portion 13 may be a transparent resin material. The maximum size of the supporting portion 13 at cross sections parallel to the surface of the base 10 ranges from 5 μm to 50 μm. In this way, the formed light homogenizing structures 311 may have a better light homogenizing effect, and the supporting portions 13 are easy to prepare. In some embodiments, the maximum size of the supporting portion 13 at the cross sections parallel to the surface of the base 10 is 5 μm, 15 μm, 25 μm, 35 μm, 45 μm, 50 μm, etc.

In an embodiment, as shown in FIG. 2 and FIG. 6, the concave structures 312 are formed on a surface of the first sub-reflective layer 31 facing the base 10. The second sub-reflective layer 32 and the third sub-reflective layer 33 are also formed with concave structures in areas thereof opposite to the concave structures 312.

In an embodiment, the supporting portion 13 may be at least one of substantially conical, substantially pyramidal, or substantially spherical-cap-shaped. “Substantially conical” refers to a conical shape as a whole, but is not limited to a standard conical shape. That is, “conical” herein includes not only a basic conical shape, but also a shape similar to a cone. “Substantially pyramidal” refers to a pyramidal shape as a whole, but is not limited to a standard pyramidal shape. That is, “pyramidal” herein includes not only a basic pyramidal shape, but also a shape similar to a pyramid. For example, cones and pyramids have curved top corners. “Substantially spherical-cap-shaped” refers to a spherical-cap shape as a whole, but is not limited to a standard spherical-cap shape. That is, “spherical-cap-shaped” herein includes not only a basic spherical-cap shape, but also a shape similar to a spherical cap. For example, an upper half of a spherical cap is a standard spherical cap, and a lower half of the spherical cap is a cylinder.

In an embodiment, when the second reflective layer 30 is located between the encapsulation layer 60 and the base 10, the supporting portions 13 are located on a side of the second reflective layer 30 facing the base 10. The supporting portions 13 may be in direct contact with the base 10. Alternatively, the second reflective layer 30 is located on a side of the encapsulation layer 60 away from the base 10, and the supporting portions 13 are located between the encapsulation layer 60 and the second reflective layer 30.

In an embodiment, as shown in FIG. 3 and FIG. 7, the light homogenizing structures 311 include a plurality of convex structures 313 arranged in an array and facing the base 10, the base 10 is provided with a plurality of concave portions 12 arranged in an array on a surface thereof facing the conductive layer 40, and the convex structures 313 are disposed within the concave portions 12. The convex structures 313 may correspond to the concave portions 12 one by one, and each of the convex structures 313 is located within a respective concave portion 12. The concave portions 12 are provided on the surface of the base 10 to facilitate the formation of the convex structures 313.

In an embodiment, as shown in FIG. 3 and FIG. 7, the convex structures 313 are formed on a side of the first sub-reflective layer 31 facing the base 10. The second sub-reflective layer 32 and the third sub-reflective layer 33 are also formed with convex structures in areas thereof opposite to the convex structures 313.

In an embodiment, the shape of the convex structure may be at least one of substantially conical, substantially pyramidal, or substantially spherical-cap-shaped.

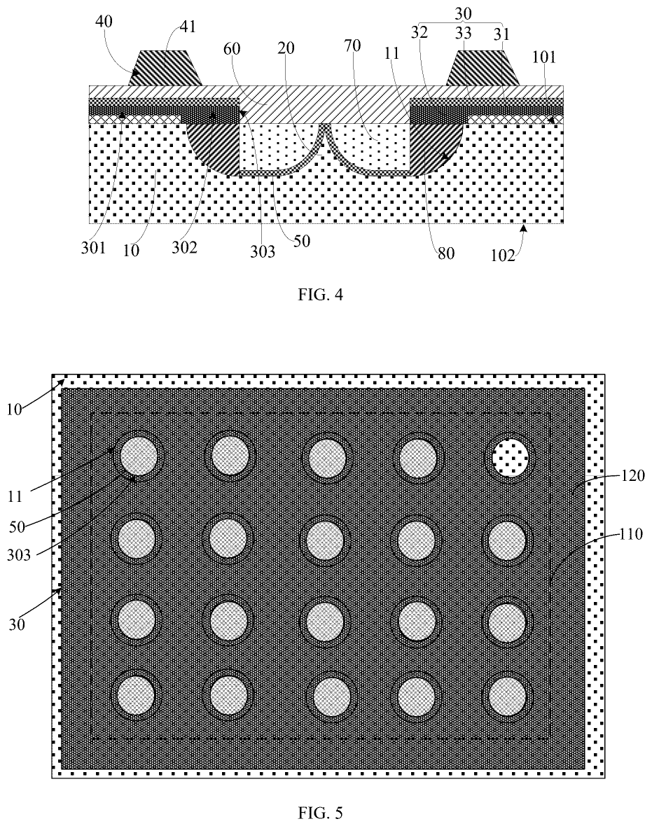

In an embodiment, as shown in FIG. 4, the array substrate further includes a transparent organic layer 80 disposed within the groove 11. There is an overlapping area between the orthographic projection of the second reflective layer 30 on the second surface 102 of the base 10 and the orthographic projection of the groove 11 on the second surface 102 of the base 10. An orthographic projection of the transparent organic layer 80 on the second surface 102 of the base 10 covers the overlapping area. In this way, the transparent organic layer 80 can support the second reflective portion 302 of the second reflective layer 30 to prevent collapse of an area of the second reflective layer 30 opposite to the groove 11. In addition, the transparent organic layer 80 is formed before the first reflective layer 50 is formed. The transparent organic layer 80 can prevent the first reflective layer 50 from extending to the side surface of the groove 11, thereby reducing the amount of light reflected by the first reflective layer 50 and emitted through the opening of the groove 11, and increasing the amount of light emitted from the second surface 102 of the base 10.

In an embodiment, as shown in FIG. 4, the orthographic projection of the transparent organic layer 80 on the second surface 102 of the base 10 coincides with the overlapping area. In this way, the transparent organic layer 80 provides better support for the second reflective portion 302. A light transmittance of the transparent organic layer may be greater than or equal to 95%, and a refractive index of the transparent organic layer is less than that of the base 10.

In an embodiment, as shown in FIG. 4, the color conversion structure 70 is located between the transparent organic layer 80 and the first reflective layer 50.

In an embodiment, as shown in FIG. 2, the second reflective portion 302 has a width of a first size d1. A longitudinal cross-section of the groove 11 is a circular arc, which has a radius of a second size d2. The first size d1 is equal to the second size d2, and is equal to a depth h of the groove 11.

Further, as shown in FIG. 2, a longitudinal cross-section of the protrusion 20 is a circular arc, which has a radius of a third size d3, where the third size d3 is equal to the depth h of the groove 11.

Embodiments of the present application further provide a method of preparing an array substrate. As shown in FIG. 8, the method includes the following steps S110 and S120.

At step S110, a groove is formed in a surface of a base, a protrusion is formed within the groove, and a first reflective layer and a second reflective layer are formed, such that the first reflective layer at least covers a side surface of the protrusion, and the second reflective layer covers an area of the base surrounding the groove.

In an embodiment, the step S110 includes the following processes.

Firstly, a mask is provided on a base substrate.

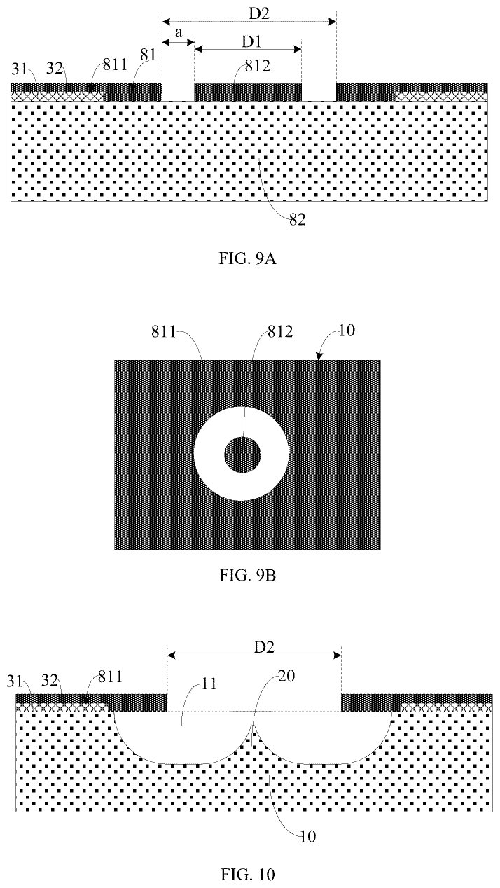

This step may result in a first intermediate structure as shown in FIG. 9A and FIG. 9B. As shown in FIG. 9A and FIG. 9B, a mask 81 is disposed on a first surface of a base substrate 82, and the mask 81 includes a first mask portion 811 and a second mask portion 812, where the first mask portion 811 is provided with a through hole, the second mask portion 812 is disposed within the through hole of the first mask portion 811, and there is a gap between the second mask portion 812 and the first mask portion 811. A surface of the second mask portion 812 may be circular, the through hole of the first mask portion 811 may be circular, and a center of the surface of the second mask portion 812 may coincide with a center of the through hole of the first mask portion 811. The surface of the second mask portion 812 has a diameter of D1, the through hole of the first mask portion 811 may have a diameter of D2, and a distance between an edge of the through hole of the first mask portion 811 and an edge of the second mask portion 812 is a, where D2=D1+2a.

In some embodiments, D1≥5 μm. The value of D1 is related to a height of a protrusion subsequently formed, and the larger D1 is, the larger the height of the formed protrusion is. By setting D1≥5 μm, it can be avoided that the height of the protrusion is too small, and thus a height of the first reflective layer covering the side surface of the protrusion is too small, such that the amount of light emitted by the light-emitting element and reflected by the first reflective layer is small, and the uniformity of the light cannot be effectively improved.

In an embodiment, a≥2 μm. In this way, it can be avoided that the distance between the edge of the through hole of the first mask portion 811 and the edge of the second mask portion 812 is too small, which affects contact between the etching solution and the base substrate.

In an embodiment, as shown in FIG. 9A, the first mask portion 811 includes a first sub-reflective layer 31 and a second sub-reflective layer 32 on a side of the first sub-reflective layer 31 away from the base substrate 82. A distance between an inner edge of the second sub-reflective layer 32 and the second mask portion 812 is less than a distance between an inner edge of the first sub-reflective layer 31 and the second mask portion 812. The second sub-reflective layer 32 covers an edge of the first sub-reflective layer facing the second mask portion 812.

Subsequently, the base substrate is etched by using a wet etching process to form the groove, thereby obtaining the base including the groove and the protrusion within the groove.

In this step, the etching solution contacts the base substrate 82 through the gap between the first mask portion 811 and the second mask portion 812, and etches the base substrate 82. Due to the presence of the second mask portion 812, an area of the base substrate 82 covered by the second mask portion 812 is not completely etched, and an area that is retained is the protrusion. This step may result in a second intermediate structure as shown in FIG. 10. As shown in FIG. 10, both the base 10 and the protrusion 20 are part of the base substrate 82, that is, the base 10 and the protrusion 20 are integrally formed. There is a gap between the protrusion 20 and a side surface of the groove 11. An orthographic projection of the second sub-reflective layer 32 of the second mask portion 812 on a surface of the base 10 away from the second sub-reflective layer 32 overlaps an orthographic projection of the groove 11 on the surface of the base 10 away from the second sub-reflective layer 32, that is, a portion of the second sub-reflective layer 32 is opposite to the groove 11.

In this step, the etching solution etches the second mask portion 812 while etching the base substrate 82. After the etching of the base substrate 82 is completed, the second mask portion 812 may be completely etched.

Due to the isotropic nature of the wet etching process, an area of a bottom surface of the groove 11 corresponding to the gap between the first mask portion 811 and the second mask portion 812 is substantially planar, that is, an area of the bottom surface of the groove 11 surrounding the protrusion 20 is substantially planar, and a width of the planar area of the bottom surface of the groove 11 is substantially equal to a. A longitudinal cross-section of the groove 11 is substantially a circular arc, a radius of a circle to which the circular arc belongs being substantially equal to the maximum depth of the groove 11. A longitudinal cross-section of the protrusion 20 is substantially a circular arc, a radius of a circle to which the circular arc belongs being substantially equal to the maximum depth of the groove 11. A radius of the circular arc-shaped longitudinal cross-section of the groove 11 is substantially the same as a width of a portion of the second sub-reflective layer 32 opposite to the groove 11.

In an embodiment, the depth of the groove 11 is greater than or equal to D1/2. When the depth of the groove 11 is equal to D1/2, a top surface of the protrusion 20 is substantially flush with a surface of the base 10 facing the first sub-reflective layer 31.

Subsequently, the first reflective layer is formed.

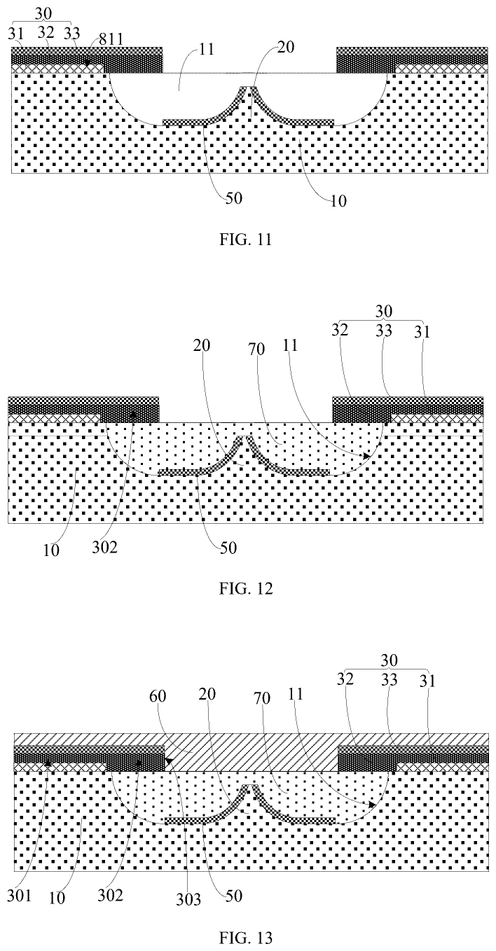

This step may result in a third intermediate structure as shown in FIG. 11. As shown in FIG. 11, a third sub-reflective layer 33 covering the second sub-reflective layer 32 is formed at the same time as the first reflective layer 50 is formed, thereby obtaining the second reflective layer 30 including the first sub-reflective layer 31, the second sub-reflective layer 32, and the third sub-reflective layer 33.

In an embodiment, after step S110, the method of preparing the array substrate further includes step of forming a color conversion structure within the groove.

This step may result in a fourth intermediate structure as shown in FIG. 12. As shown in FIG. 12, a surface of the color conversion structure 70 facing the second sub-reflective layer 32 may be flush with a surface of the base 10 facing the second sub-reflective layer 32. In other embodiments, the surface of the color conversion structure 70 facing the second sub-reflective layer 32 may be lower than the surface of the base 10 facing the second sub-reflective layer 32.

In another embodiment, if the light-emitting element emits white light, after step S110, the method of preparing the array substrate further includes the process of forming a transparent organic layer within the groove.

In an embodiment, after the step of forming the color conversion structure within the groove, the method of preparing the array substrate further includes step of forming an encapsulation layer covering the color conversion structure.

This step may result in a fifth intermediate structure as shown in FIG. 13. As shown in FIG. 13, the encapsulation layer 60 covers the color conversion structure 70 and the second reflective layer 30.

At step S120, a conductive layer is formed on a side of the second reflective layer away from the base, the conductive layer including one or more conductive pads.

This step may result in the array substrate as shown in FIG. 1A.

In an embodiment, before the step S110, the method of preparing the array substrate further includes step of forming a plurality of supporting portions on a surface of the base substrate.

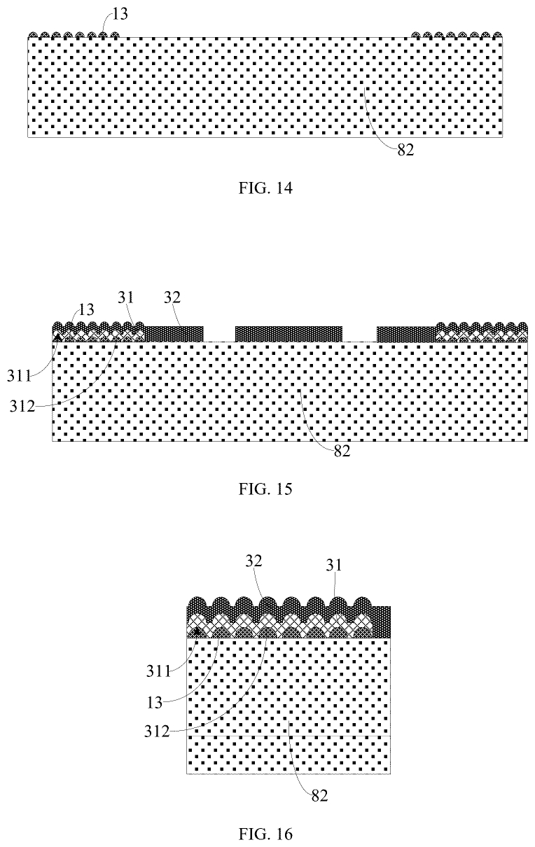

This step may result in a sixth intermediate structure as shown in FIG. 14. As shown in FIG. 14, a plurality of supporting portions 13 are formed on a surface of the base substrate 82, and a continuous area of the surface of the base substrate 82 without the supporting portions 13 may be substantially circular. In some embodiments, the surface of the base substrate 82 may be coated with a resin material, and then the resin material may be patterned to obtain the plurality of supporting portions 13.

In this embodiment, a first intermediate structure as shown in FIG. 15 and FIG. 16 can be obtained after the step of forming the mask on the base substrate. As shown in FIG. 15 and FIG. 16, a light homogenizing structure 311 is formed in an area of a surface of the first sub-reflective layer 31 facing the base 10 that contacts the supporting portion 13, and the light homogenizing structure 311 is a concave structure 312. The second sub-reflective layer is also formed with a concave structure in an area corresponding to the concave structure 312.

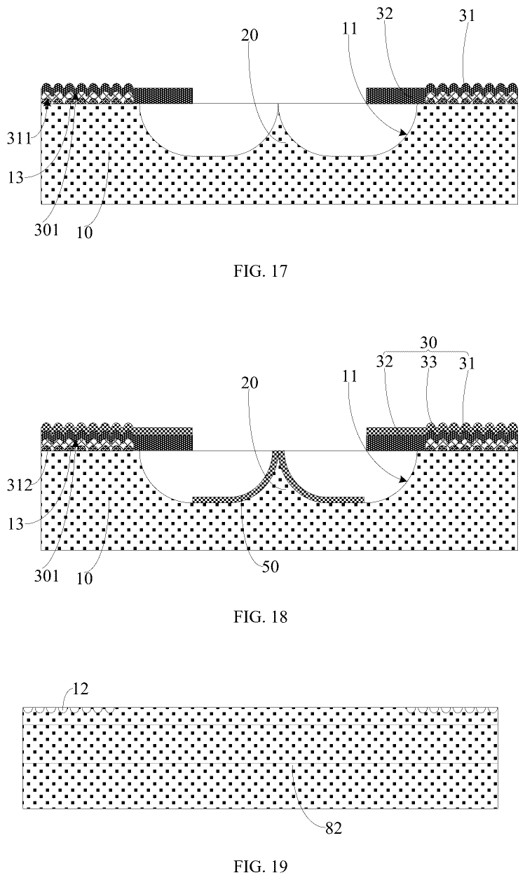

In this embodiment, after the step of etching the base substrate by using the wet etching process to form the groove, a second intermediate structure as shown in FIG. 17 is obtained.

In this embodiment, after the step of forming the first reflective layer, a third intermediate structure as shown in FIG. 18 can be obtained. As shown in FIG. 18, a third sub-reflective layer 33 covering the second sub-reflective layer 32 is formed at the same time as the first reflective layer 50 is formed, and the third sub-reflective layer 33 is formed with a concave structure in an area corresponding to the concave structure 312 of the first sub-reflective layer 31.

In this embodiment, the resulting array substrate is shown in FIG. 2.

In an embodiment, before the step S110, the method of preparing the array substrate further includes step of forming a plurality of concave portions on a surface of the base substrate.

This step may result in a seventh intermediate structure as shown in FIG. 19. As shown in FIG. 19, a plurality of concave portions 12 arranged at intervals are formed on a surface of the base substrate 82, and a continuous area of the surface of the base substrate 82 without the concave portions 12 may be substantially circular. In this step, a mask may be formed on the surface of the base substrate 82, and then the base substrate may be etched with an etching solution to form the concave portions. When the material of the base substrate is glass, the etching solution may include hydrofluoric acid, and the material of the mask may be molybdenum. The mask is removed after the concave portions are formed.

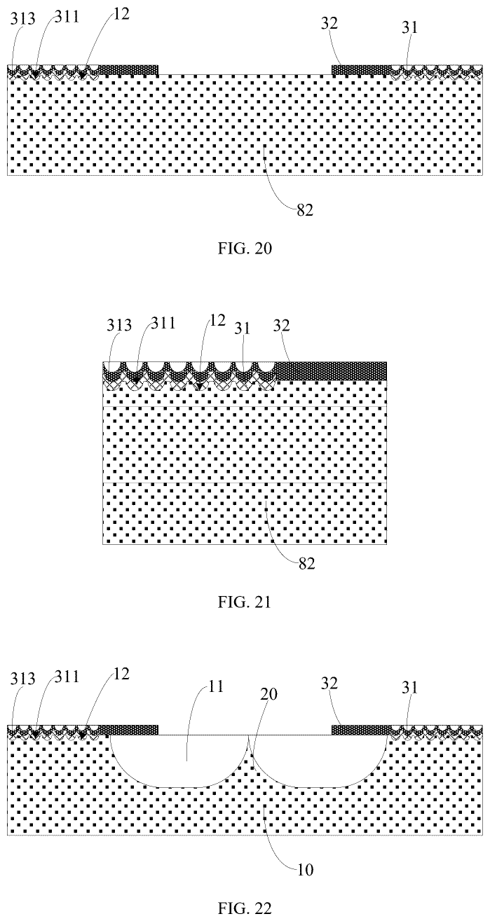

In this embodiment, a first intermediate structure as shown in FIG. 20 and FIG. 21 can be obtained after the step of forming the mask on the base substrate. As shown in FIG. 20 and FIG. 21, a plurality of light homogenizing structures 311 are formed on a surface of the first sub-reflective layer 31 facing the base 10. The light homogenizing structures 311 are convex structures 313 disposed within the concave portions 12, and the second sub-reflective layer 32 is also formed with convex structures in an area corresponding to the convex structures 313.

In this embodiment, after the step of etching the base substrate by using the wet etching process to form the groove, a second intermediate structure as shown in FIG. 22 is obtained.

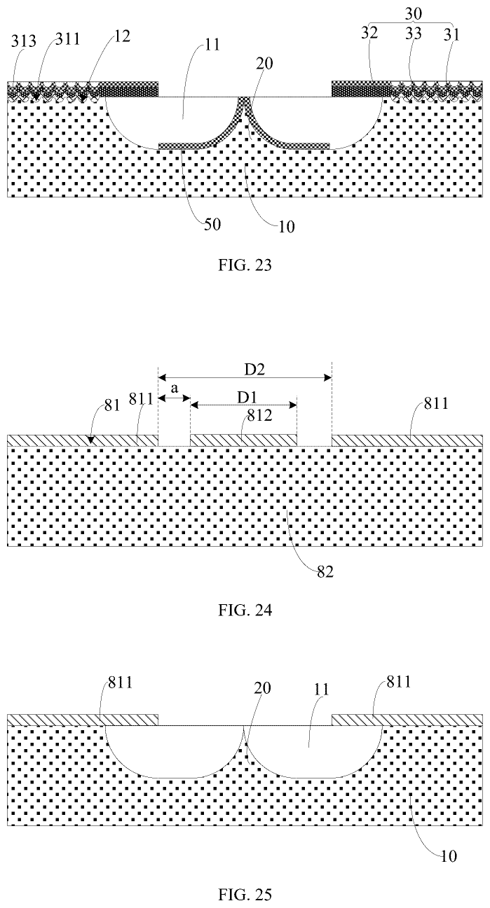

In this embodiment, after the step of forming the first reflective layer, a third intermediate structure as shown in FIG. 23 can be obtained. As shown in FIG. 23, a third sub-reflective layer 33 covering the second sub-reflective layer 32 is formed at the same time as the first reflective layer 50 is formed, and the third sub-reflective layer 33 is formed with convex structures in an area corresponding to the convex structures 313 of the first sub-reflective layer 31.

In this embodiment, the resulting array substrate is shown in FIG. 3.

In an embodiment, the step S110 of forming the groove on the surface of the base, forming the protrusion within the groove, and forming the first reflective layer and the second reflective layer, such that the first reflective layer at least covers the side surface of the protrusion, and the second reflective layer covers the area of the base surrounding the groove, includes the following processes.

First, a mask is formed on a base substrate.

This step may result in a first intermediate structure as shown in FIG. 24. The first intermediate structure shown in FIG. 24 differs from the first intermediate structure shown in FIG. 9A is in that, the first mask portion 811 and the second mask portion 812 each include only one film layer, and the material of the first mask portion 811 and the second mask portion 812 may be molybdenum.

Subsequently, the base substrate is etched by using a wet etching process to form the groove, thereby obtaining the base including the groove and the protrusion within the groove.

This step may result in a second intermediate structure as shown in FIG. 25. The second intermediate structure shown in FIG. 25 differs from the second intermediate structure shown in FIG. 10 in that the first mask portion 811 includes only one film layer.

Subsequently, the first mask portion 811 is removed.

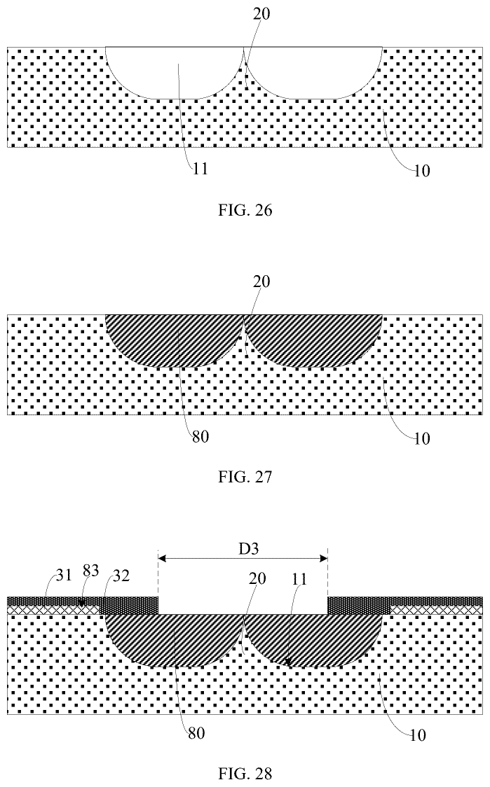

This step may result in an eighth intermediate structure as shown in FIG. 26. In this step, the first mask portion 811 may be removed by using a wet etching process.

Subsequently, a transparent organic layer is filled in the groove.

This step may result in a ninth intermediate structure as shown in FIG. 27. As shown in FIG. 27, the groove 11 is completely filled with a transparent organic layer 80, and a surface of the transparent organic layer 80 may be flush with a surface of the base 10 on the same side. A material of the transparent organic layer 80 may be an organic resin.

Subsequently, a mask layer is formed on a surface of the base on the same side as the opening of the groove.

This step may result in a tenth intermediate structure as shown in FIG. 28. As shown in FIG. 28, the mask layer 83 is provided with a through hole, which may be circular, and a center of the opening of the groove 11 may coincide with a center of the through hole. The through hole of the mask layer 83 has a diameter D3, and D3 may be substantially equal to D2.

In an embodiment, as shown in FIG. 28, the mask layer 83 includes a first sub-reflective layer 31 and a second sub-reflective layer 32 on a side of the first sub-reflective layer 31 away from the base 10. A distance between an edge of the second sub-reflective layer 32 and the groove 11 is less than a distance between an inner edge of the first sub-reflective layer 31 and the groove 11. The second sub-reflective layer 32 covers a portion of the transparent organic layer 80, and there is a gap between the first sub-reflective layer 31 and an outer edge of the transparent organic layer 80.

Subsequently, the transparent organic layer is etched by using a wet etching process to remove an area of the transparent organic layer which is not covered by the mask layer.

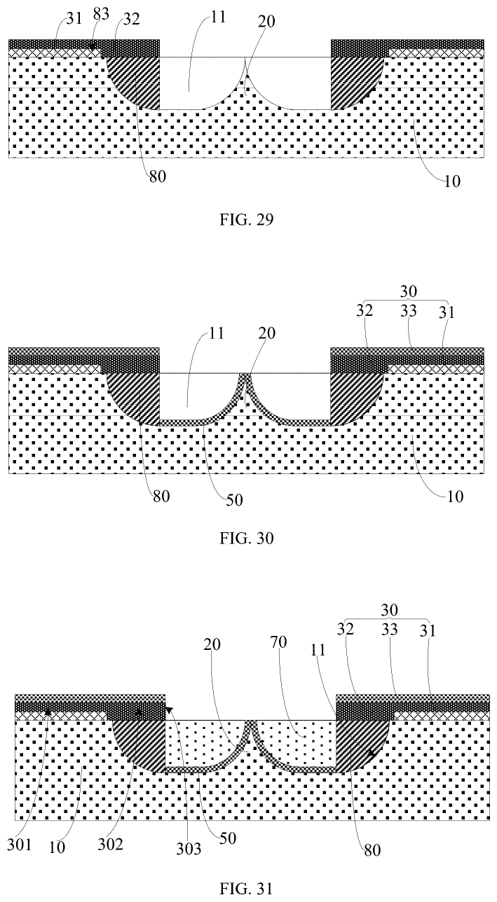

In this step, when the material of the transparent organic layer 80 is a transparent organic resin, the transparent organic layer 80 may be etched by using a dry etching process. This step may result in an eleventh intermediate structure as shown in FIG. 29. As shown in FIG. 29, an area of the transparent organic layer 80 covered by the second sub-reflective layer 32 is retained, and the retained transparent organic layer 80 can support the second sub-reflective layer 32 to prevent collapse of the second sub-reflective layer 32.

Subsequently, the first reflective layer is formed.

This step may result in a twelfth intermediate structure as shown in FIG. 30. As shown in FIG. 30, a third sub-reflective layer 33 covering the second sub-reflective layer 32 is formed at the same time as the first reflective layer 50 is formed, thereby obtaining the second reflective layer 30 including the first sub-reflective layer 31, the second sub-reflective layer 32, and the third sub-reflective layer 33. In this step, since the transparent organic layer 80 is formed within the groove 11 to cover the side surface of the groove 11, the first reflective layer 50 formed may be prevented from covering the side surface of the groove 11.

Subsequently, a color conversion structure is formed within the groove.

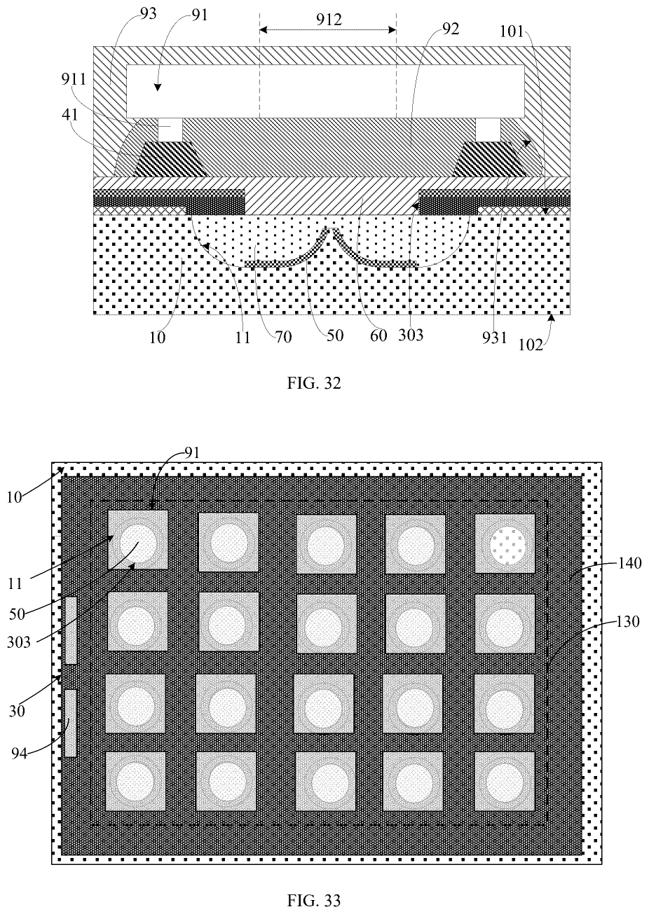

This step may result in a thirteenth intermediate structure as shown in FIG. 31. As shown in FIG. 31, the color conversion structure 70 is disposed between the transparent organic layer 80 and the protrusion 20.

Subsequently, an encapsulation layer is formed to cover the color conversion structure 70.

In this embodiment, the resulting array substrate is shown in FIG. 4.

The embodiments of the method of preparing the array substrate according to the present application and the embodiments of the array substrate belong to the same inventive concept, and the description of the relevant details and beneficial effects can be referred to each other, and will not be repeated herein.

Embodiments of the present application further provide a light-emitting substrate. The light-emitting substrate includes a plurality of light-emitting elements and the array substrate according to any one of the above embodiments. The array substrate in the light-emitting substrate shown in FIG. 32 is the array substrate shown in FIG. 1A, but is not limited thereto. As shown in FIG. 32, each of the light-emitting elements 91 includes a plurality of pins 911, each of which is bound and connected to one of the conductive pads 41.

In an embodiment, as shown in FIG. 32, each of the light-emitting elements 91 includes a light-exit area 912, an orthographic projection of which on the second surface 102 of the base 10 falls within an orthographic projection of a respective color conversion structure 70 on the second surface 102 of the base 10. It should be noted that the light-exit area 912 is an area through which the light emitted by the light-emitting element 91 can be emitted when the light-emitting element 91 is in operation. The pins 911 of the light-emitting element 91 are usually made of a metal or alloy material with better electrical conductivity, and the light emitted by the light-emitting element 91 can be emitted from areas other than an area where the pins 911 are located. In FIG. 32, the light-exit area 912 is located between the pins 911, and the light-exit area 912 is not necessarily a regular area in practice.

In an embodiment, an edge of an orthographic projection of a light-emitting area of each light-emitting element 91 on the second surface 102 of the base 10 is located inward of an edge of an orthographic projection of a respective opening 303 of the second reflective layer 30 on the second surface 102 of the base 10. In this way, the light emitted by the light-emitting element 91 can be prevented from being incident to a surface of the second reflective layer 30 away from the base 10 to be reflected, which helps to reduce the light loss.

In an embodiment, as shown in FIG. 32, the light-emitting substrate further includes a third reflective layer 93, where the third reflective layer 93 covers the light-emitting element 91, and the third reflective layer 93 is provided with a light-exit hole 931 on a side thereof facing the array substrate. An orthographic projection of the light-exit area 912 of the light-emitting element 91 on the second surface 102 of the base 10 falls within an orthographic projection of the light-exit hole 931 on the second surface 102 of the base 10. The light emitted by the light-emitting element 91 from a non-light-emitting area may exit through the light-exit hole 931 to be reflected by the third reflective layer 93, so as to improve the utilization of the light. The third reflective layer 93 may cover a surface of the light-emitting element 91 away from the array substrate, a side surface of the light-emitting element 91, and a portion of a surface of the light-emitting element 91 facing the array substrate.

In an embodiment, a material of the third reflective layer 93 includes at least one of white ink or silicon-based white glue. For example, the material of the third reflective layer 93 may be white ink or silicon-based white glue.

In an embodiment, as shown in FIG. 32, the light-emitting substrate further includes an insulating protection layer 92. The insulating protection layer 92 covers the pins 911 of the light-emitting element 91 and the conductive pads 41, to protect the pins 911 of the light-emitting element 91 and the conductive pads 41. A material of the insulating protection layer 92 may be a transparent resin material, which has a light transmittance greater than 95%.

In an embodiment, the light-emitting element 91 may include a Micro LED and/or a Mini LED. The Micro LED has a size (e.g., length) of less than 50 μm, e.g., 10 μm to 50 μm. The Mini LED has a size (e.g., length) of 50 μm to 150 μm, e.g., 80 μm to 120 μm.

In an embodiment, as shown in FIG. 33, the light-emitting substrate includes a light-emitting area 130 and a peripheral area 140. A boundary of the light-emitting area 130 may coincide with a boundary of the central area of the base, and a boundary of the peripheral area 140 may coincide with a boundary of the edge area of the base. The light-emitting elements 91 are disposed in the light-emitting area 130.

In an embodiment, the conductive layer 40 includes a plurality of conductive pads 41 divided into a plurality of groups of conductive pads. Each of the light-emitting elements is bound and connected to the conductive pads 41 in one group of conductive pads. The number of the pins 911 of the light-emitting element 91 is the same as the number of the conductive pads 41 in the corresponding group of conductive pads, and each of the pins 911 is bound and connected to one of the conductive pads 41.

In an embodiment, as shown in FIG. 33, the light-emitting substrate further includes one or more non-light-emitting elements 94, such as driver chips or sensor chips. An orthographic projection of the non-light-emitting elements 94 on the second surface 102 of the base 10 does not overlap the orthographic projection of the groove 11 on the second surface 102 of the base 10. Each of the non-light-emitting elements 94 includes pins, which are bound and connected to the conductive pads in one group of conductive pads. The number of the pins of the non-light-emitting element 94 is the same as the number of the conductive pads in the corresponding group of conductive pads. The non-light-emitting elements 94 may be located in the peripheral area 140.

It should be noted that FIG. 33 is a schematic diagram, and in practice, the number of the light-emitting elements 91 included in the light-emitting substrate is much larger than the number of the light-emitting elements 91 in FIG. 33.

Embodiments of the present application further provide a display apparatus, including a display panel and the light-emitting substrate as described above. The display panel is located on a side of the base away from the light-emitting element.

The display apparatus can be a liquid crystal display apparatus, and the array substrate is used as a backlight module.

The application of the display apparatus is not specifically limited in the present application, and the display apparatus can be any product or component with a flexible display function, such as a television, a notebook computer, a tablet computer, a wearable display device, a mobile phone, a vehicle-mounted display, a navigation, an electronic book, a digital photo frame, and an advertising lamp box.

It should be noted that in the drawings, sizes of layers and areas may be exaggerated for clarity of illustration. It can be understood that when an element or layer is referred to as being “on” another element or layer, it may be directly on the other element, or there may be intervening layers. Also, it can be understood that when an element or layer is referred to as being “under” another element or layer, it may be directly under the other element, or there may be more than one intervening layer or element. Additionally, it can be understood that when a layer or element is referred to as being “between” two layers or elements, it may be that only layer between the two layer or elements, or there may be more than one intervening layer or element. Like reference numerals indicate like elements throughout.

Other embodiments of the present application will occur to those skilled in the art upon consideration of the specification and practice of the disclosure herein. The present application is intended to cover any variations, uses, or adaptations of the present application that follow the general principles of the present application and include common general knowledge or commonly used technical means in the art not disclosed herein. The specification and embodiments are to be considered as exemplary only, with a true scope and spirit of the present application being indicated by the following claims.

It should be understood that the present application is not limited to the precise structures which have been described above and illustrated in the drawings, and that various modifications and changes may be made without departing from the scope thereof. The scope of the present application is limited only by the appended claims.

1. An array substrate, comprising:
a base comprising a first surface and a second surface opposite to each other, the first surface being provided with a groove;
a protrusion disposed within the groove and spaced apart from a side surface of the groove, wherein areas of cross sections of the protrusion parallel to the second surface gradually increase in a direction from the first surface to the second surface;
a first reflective layer at least covering a side surface of the protrusion;
a second reflective layer disposed on a side of the base away from the second surface, the second reflective layer being provided with an opening, and an orthographic projection of the opening on the second surface being within an orthographic projection of the groove on the second surface; and
a conductive layer on a side of the second reflective layer facing away from the base, the conductive layer comprising one or more conductive pads.

2. The array substrate according to claim 1, wherein the second reflective layer comprises a first reflective portion, an orthographic projection of the first reflective portion on the second surface does not overlap the orthographic projection of the groove on the second surface, and the first reflective portion is provided with a plurality of light homogenizing structures arranged in an array on a surface facing the base.

3. The array substrate according to claim 2, wherein the light homogenizing structures comprise a plurality of concave structures arranged in an array, the array substrate further comprises a plurality of supporting portions arranged in an array and disposed between the second reflective layer and the base, and the second reflective layer is in direct contact with the supporting portions.

4. The array substrate according to claim 3, further comprising an encapsulation layer disposed between the base and the conductive layer,
wherein the second reflective layer is disposed between the encapsulation layer and the base and the supporting portions are disposed on a side of the second reflective layer facing the base; or wherein the second reflective layer is disposed on a side of the encapsulation layer away from the base and the supporting portions are disposed between the second reflective layer and the encapsulation layer.

5. The array substrate according to claim 2, wherein the light homogenizing structures comprise a plurality of convex structures arranged in an array and facing the base, a plurality of concave portions are disposed on the first surface of the base, and the convex structures are disposed within the concave portions.

6. The array substrate according to claim 1, wherein
an edge of the orthographic projection of the opening on the second surface is disposed inward of an edge of the orthographic projection of the groove on the second surface; and
an orthographic projection of the second reflective layer on the second surface does not overlap an orthographic projection of the protrusion on the second surface.

7. The array substrate according to claim 6, wherein
the second reflective layer comprises a second reflective portion, an orthographic projection of the second reflective portion on the second surface falling within the orthographic projection of the groove on the second surface;
the second reflective portion has a width of a first size;
a longitudinal cross-section of the groove is a circular arc, which has a radius of a second size; and
the first size is equal to the second size and is equal to a depth of the groove.

8. The array substrate according to claim 7, wherein a longitudinal cross-section of the protrusion is a circular arc, which has a radius of a third size, wherein the third size is equal to the depth of the groove.

9. The array substrate according to claim 1, wherein an orthographic projection of the second reflective layer on the second surface overlaps an orthographic projection of the first reflective layer on the second surface.

10. The array substrate according to claim 1, wherein
the second reflective layer comprises a first sub-reflective layer, a second sub-reflective layer on a side of the first sub-reflective layer away from the base, and a third sub-reflective layer on a side of the second sub-reflective layer away from the base;
an orthographic projection of the first sub-reflective layer on the second surface does not overlap the orthographic projection of the groove on the second surface, and the first sub-reflective layer has a reflectivity greater than that of the second sub-reflective layer; and
an orthographic projection of the second sub-reflective layer on the second surface overlaps the orthographic projection of the groove on the second surface, the third sub-reflective layer covers the second sub-reflective layer, and the third sub-reflective layer and the first reflective layer are made of a same material.

11. The array substrate according to claim 1, wherein a distance between a surface of the protrusion away from the second surface and the second surface is less than or equal to a distance between the first surface and the second surface;
wherein areas of cross sections of the groove parallel to the second surface gradually decrease in the direction from the first surface to the second surface; and
wherein a bottom surface of the groove is planar in an area on both sides of the protrusion.

12-13. (canceled)

14. The array substrate according to claim 1, wherein an orthographic projection of a geometric center of the protrusion on the second surface coincides with an orthographic projection of a geometric center of the groove on the second surface.

15. The array substrate according to claim 14, wherein an outer contour of an orthographic projection of the protrusion on the second surface is a circle, and an outer contour of the orthographic projection of the groove on the second surface is a circle.

16. The array substrate according to claim 15, wherein a ratio of a radius of the outer contour of the orthographic projection of the protrusion on the second surface to a radius of the outer contour of the orthographic projection of the groove on the second surface is less than 0.5.

17. The array substrate according to claim 1, wherein the protrusion and the base are made of a same material; and
wherein the protrusion and the base are of a monolithic structure.

18-19. (canceled)

20. The array substrate according to claim 1, wherein
the array substrate further comprises a transparent organic layer disposed within the groove, an orthographic projection of the transparent organic layer on the second surface covering an overlapping area between an orthographic projection of the second reflective layer on the second surface and the orthographic projection of the groove on the second surface.

21. The array substrate according to claim 1, further comprising an encapsulation layer between the base and the conductive layer,
wherein the second reflective layer comprises a conductive material; and
the encapsulation layer comprises an inorganic film layer and an organic film layer, an orthographic projection of the organic film layer on the second surface covering an orthographic projection of the second reflective layer on the second surface.

22. (canceled)

23. A light-emitting substrate, comprising a plurality of light-emitting elements and the array substrate of claim 1, wherein each of the light-emitting elements comprises a plurality of pins, and each of the pins is bound and connected to one of the conductive pads.

24. The light-emitting substrate according to claim 23, wherein the light-emitting substrate further comprises a third reflective layer, wherein the third reflective layer covers the light-emitting elements, and the third reflective layer is provided with a light-exit hole on a side facing the array substrate.

25. A display apparatus, comprising a display panel and the light-emitting substrate of claim 23, wherein the display panel is disposed on a side of the base away from the light-emitting elements.
